(19) United States
(12) Patent Application Publication
(10) Pub. No.: US 2025/0101566 A1
(43) Pub. Date: Mar. 27, 2025

(54) MASK PLATE, AND ELECTRONIC APPARATUS AND MANUFACTURING METHOD THEREFOR

(71) Applicants: BOE MLED Technology Co., Ltd., Beijing (CN); BOE Technology Group Co., Ltd., Beijing (CN)

(72) Inventors: Enkai DONG, Beijing (CN); Yutian CHU, Beijing (CN); Ming ZHAI, Beijing (CN); Jiacheng QI, Beijing (CN); Le WANG, Beijing (CN); Qiqi ZHOU, Beijing (CN)

(21) Appl. No.: 18/705,571

(22) PCT Filed: Apr. 28, 2023
(86) PCT No.: PCT/CN2023/091545

§ 371 Date: Apr. 28, 2024

(30) Foreign Application Priority Data
Jun. 17, 2022 (CN) 202210692145.7

(51) Int. Cl. C23C 14/04

(52) U.S. Cl. CPC C23C 14/042

(57) ABSTRACT

A back plate includes a substrate, and an insulation layer and a pad group that are located on the substrate. The pad group includes at least two pads. The insulation layer includes openings. The pads protrude towards a side away from the substrate relative to the insulation layer. A mask includes through holes and a blind hole. The orthographic projections of the through holes on the substrate overlap orthographic projections of the pads on the substrate. The blind hole surrounds the through holes. A size of the blind hole in a thickness direction of the mask is greater than or equal to a size of the pad protruding from the insulation layer. An orthographic projection of the blind hole on the substrate and the orthographic projections of the through holes on the substrate after spliced cover the orthographic projections of the pads on the substrate.

### CROSS-REFERENCE TO RELATED APPLICATION

The disclosure is a national phase entry under 35 U.S.C. § 371 of International Application No. PCT/CN2023/091545, filed on Apr. 28, 2023, which claims the benefit of priority to Chinese patent application No. 202210692145.7, filed with the China National Intellectual Property Administration (CNIPA) on Jun. 17, 2022 and entitled “Mask, and electronic apparatus and manufacturing method therefor”, the entire contents of which are incorporated herein by reference.

### TECHNICAL FIELD

The disclosure relates to the technical field of display, and particularly relates to a mask, and an electronic apparatus and a manufacturing method therefor.

### BACKGROUND

Surface mounted technology (SMT), the most prevalent technology and process in the electronic assembly industry, is used to weld and assemble an electronic element having pins placed on a surface of a substrate having a pad through reflow soldering, immersion soldering, etc. In order to fixedly connect the electronic element to the pad, it is required to arrange solder on the pad, which is to be electrically connected to the electronic element, of the substrate, and then fixedly connect the electronic element to the pad through a series of processes.

### SUMMARY

Specific solutions of a mask, and an electronic apparatus and a manufacturing method therefor provided in embodiments of the disclosure are as follows.

In one aspect, embodiments of the disclosure provide a mask. The mask is configured to mask a back plate. The back plate includes a substrate, and an insulation layer and a pad group that are located on the substrate. The pad group includes at least two pads. The insulation layer includes openings. The pads protrude towards a side away from the substrate relative to the insulation layer at the openings.

The mask includes:
through holes, where orthographic projections of the through holes on the substrate overlap orthographic projections of the pads on the substrate; and
a blind hole, where the blind hole surrounds the through holes, a size of the blind hole in a thickness direction of the mask is greater than or equal to a size of the pad protruding from the insulation layer, and an orthographic projection of the blind hole on the substrate and the orthographic projections of the through holes on the substrate cover the orthographic projections of the pads on the substrate after spliced.

In some embodiments, in the above mask provided in embodiments of the disclosure, the size of the blind hole in the thickness direction of the mask is less than or equal to ⅓ of a thickness of the mask.

In some embodiments, in the above mask provided in embodiments of the disclosure, the orthographic projection of the through hole on the substrate is located within the orthographic projection of the pad on the substrate.

In some embodiments, in the above mask provided in embodiments of the disclosure, the back plate includes a plurality of pixel regions. At least every two adjacent through holes form a through hole group corresponding to one pad group. One pixel region corresponds to at least two through hole groups. One blind hole surrounds through holes in the at least two through hole groups corresponding to one pixel region.

In some embodiments, in the above mask provided in embodiments of the disclosure, the orthographic projection of the through hole on the substrate is located within an orthographic projection of the pad group on the substrate. The orthographic projection of the through hole on the substrate overlaps orthographic projections of the at least two pads of the pad group on the substrate and an orthographic projection of a space between the pads on the substrate.

In some embodiments, in the above mask provided in embodiments of the disclosure, one blind hole surrounds one through hole.

In some embodiments, in the above mask provided in embodiments of the disclosure, the orthographic projection of the blind hole on the substrate extends in a direction away from the through hole relative to the orthographic projection of the pad on the substrate.

In some embodiments, in the above mask provided in embodiments of the disclosure, a distance between an orthographic projection of a boundary of the blind hole away from the through hole on the substrate and the orthographic projection of the pad on the substrate is greater than or equal to 30 μm.

In some embodiments, in the above mask provided in embodiments of the disclosure, a distance between two adjacent blind holes is greater than or equal to 100 μm.

In another aspect, embodiments of the disclosure provide an electronic apparatus. The electronic apparatus includes an electronic element and a back plate. The electronic element is electrically connected to a pad group. The back plate is masked by the above mask provided in embodiments of the disclosure.

In yet another aspect, embodiments of the disclosure provide a manufacturing method for the above electronic apparatus. The method includes:
aligning the above mask provided in embodiments of the disclosure with a back plate, and enabling through holes to be arranged opposite pads;
controlling the mask not to make contact with the pads in a region where a blind hole is located, and to make contact with an insulation layer in regions other than the region where the blind hole is located;
moving a scraper in a specific direction on the mask, pushing a welding material into the through holes, and enabling the welding material to fall onto the pads through the through holes;
removing the mask from the back plate;
placing pins of an electronic element on the welding material of the pads; and
processing the welding material through a reflow soldering process, and soldering the pins of the electronic element to the pads correspondingly.

### BRIEF DESCRIPTION OF FIGURES

FIG. 1 is a schematic diagram of a mask and a back plate after alignment and contact in the related art.

FIG. 2 is a schematic structural diagram of a back plate according to an embodiment of the disclosure.

FIG. 3 is a schematic structural diagram of a mask according to an embodiment of the disclosure.

FIG. 4 is a schematic diagram of the back plate shown in FIG. 2 and the mask shown in FIG. 3 after alignment and contact.

FIG. 5 is a sectional view along I-I′ in FIG. 4.

FIG. 6 is a sectional view along II-II′ in FIG. 4.

FIG. 7 is another schematic structural diagram of a back plate according to an embodiment of the disclosure.

FIG. 8 is another schematic structural diagram of a mask according to an embodiment of the disclosure.

FIG. 9 is a schematic diagram of the back plate shown in FIG. 7 and the mask shown in FIG. 8 after alignment and contact.

FIG. 10 is a sectional view along III-III′ in FIG. 9.

FIG. 11 is a sectional view along IV-IV′ in FIG. 9.

FIG. 12 is a schematic diagram of an electrical connection between an electronic element and a pad group in an electronic apparatus according to an embodiment of the disclosure.

FIG. 13 is a flow diagram of a manufacturing method for an electronic apparatus according to an embodiment of the disclosure.

FIG. 14 is a schematic diagram of alignment between a mask and a back plate according to an embodiment of the disclosure.

FIG. 15 is a schematic diagram of a mask and a back plate in a masking process according to an embodiment of the disclosure.

FIG. 16 is another schematic diagram of a mask and a back plate in a masking process according to an embodiment of the disclosure.

FIG. 17 is a schematic diagram of separation of a mask from a back plate according to an embodiment of the disclosure.

FIG. 18 is a schematic diagram of alignment between an electronic element and a pad group according to an embodiment of the disclosure.

### DETAILED DESCRIPTION

In order to make objectives, technical solutions and advantages of embodiments of the disclosure clearer, technical solutions of the embodiments of the disclosure will be clearly and completely described below in combination with accompanying drawings in the embodiments of the disclosure. It should be noted that sizes and shapes of all figures in accompanying drawings do not reflect true scales and are merely intended to illustrate contents of the disclosure. Moreover, the same or similar reference numerals denote the same or similar elements or elements having the same or similar functions throughout.

Unless otherwise defined, technical terms or scientific terms used herein should have the ordinary meanings understood by those of ordinary skill in the art to which the disclosure belongs. “First”, “second” and other similar words used in the description and the claims of the disclosure do not indicate any order, quantity or importance, but are merely used to distinguish between different components. “Comprise”, “include” and other similar words mean that an element or object appearing before the word contains elements or objects listed after the word and their equivalents, without excluding other elements or objects. Terms “inner”, “outer”, “above”, “under”, etc. are merely used to indicate relative positional relations, and when the absolute position of a described object changes, the relative position may change accordingly.

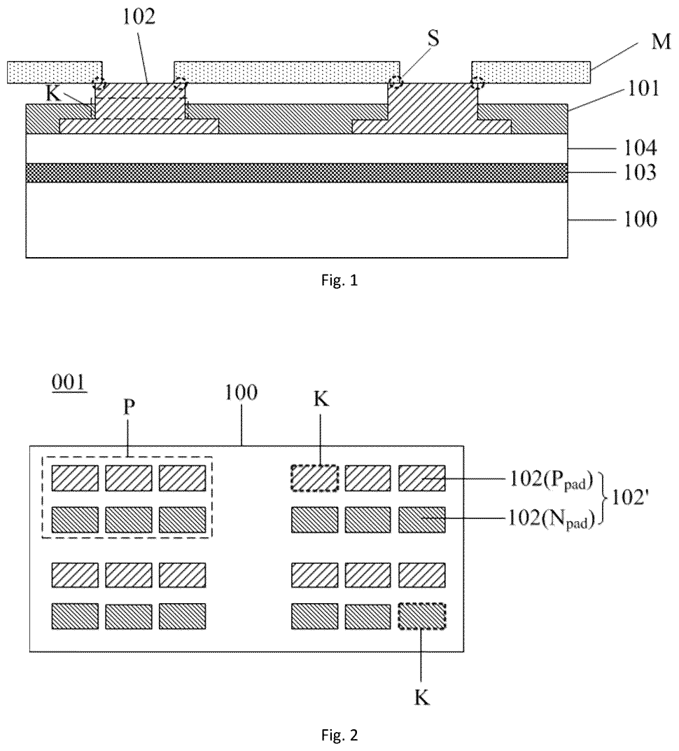

As shown in FIG. 1, the insulation layer 101 has openings K in the related art. A surface of a pad 102 exposed by the opening K is higher than a surface of the insulation layer 101 by 1 μm-3 μm. In a case that a flat mask M is used to place a welding material, in order to avoid a short circuit between adjacent pads, an area of the opening K of the flat mask M is less than an area of a surface of the pad 102. That is, the flat mask M makes contact with edges of the pads 102. A scraper is moved in a specific direction such that the welding material can fall onto the pads through the openings K. Stress concentration occurs at positions S where the pads 102 make contact with the flat mask M in the process that the scraper is moved. Moreover, since each film layer of the back plate is thin and fragile, a circuit of the back plate is often damaged due to stress in the process that the welding material is placed.

In embodiments of the disclosure, the welding material includes any one of a solder metal or a welding auxiliary material.

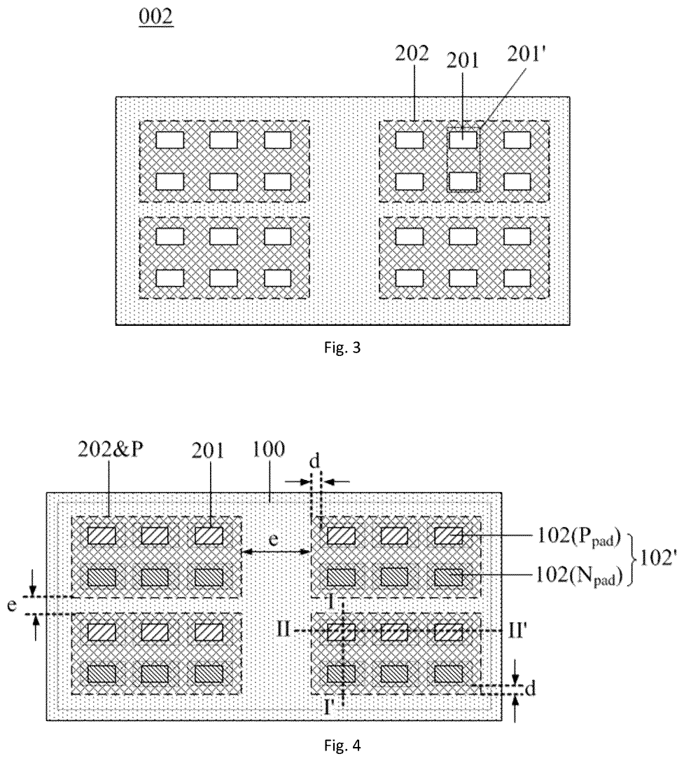

On the basis of this, as shown in FIG. 2-FIG. 6, embodiments of the disclosure provide a mask 002. The mask 002 is configured to mask a back plate 001. The back plate 001 includes a substrate 100, and an insulation layer 101 and a pad group 102′ that are located on the substrate 100. The pad group 102′ includes at least two pads 102. The insulation layer 101 includes openings K. The pads 102 protrude towards a side away from the substrate 100 relative to the insulation layer 101 at openings K.

The mask 002 includes:
through holes 201, where orthographic projections of the through holes 201 on the substrate 100 overlap orthographic projections of the pads 102 on the substrate 100; and
a blind hole 202, where the blind hole 202 surrounds the through holes 201, size ‘a’ of the blind hole 202 in a thickness direction Z of the mask 002 is greater than or equal to size ‘b’ of the pad 102 protruding from the insulation layer 101. An orthographic projection of the blind hole 202 on the substrate 100 and the orthographic projections of the through holes 201 on the substrate 100 after spliced cover the orthographic projections of the pads 102 on the substrate 100.

In the above mask 002 provided in embodiments of the disclosure, the blind hole 202 is arranged around the through holes 201 of the mask 002, and size ‘a’ (that is, a depth) of the blind hole 202 in the thickness direction Z of the mask 002 is set to be greater than or equal to size ‘b’ of the pad 102 protruding from the insulation layer 101. The orthographic projection of the blind hole 202 on the substrate 100 and the orthographic projections of the through holes 201 on the substrate 100 after spliced cover the orthographic projections of the pads 102 on the substrate 100. The mask 002 is placed on the back plate 001 after alignment. Specifically, a position of the blind hole 202 of the mask 002 do not make contact with the pads 102, and other portions of the mask 002 except for the position of the blind hole 202 make contact with the insulation layer 101, such that stress concentration caused by an overlap between the mask 002 and an edge of the pad 102 is avoided. Therefore, the problem of a damage to a circuit of the back plate 001 caused by stress concentration can be effectively solved.

Optionally, the pad group 102′ includes two pads 102, which are first pad P_{pad} and second pad N_{pad} that are electrically connected to pins of a two-pin electronic element (e.g., a light-emitting diode) respectively. The material of the pad 102 in the disclosure may include nickel and/or aurum. In some embodiments, a nickel (Ni) layer having a thickness of 3 μm-5 μm may be first formed on an electrically-conductive pattern (e.g., a trace structure made of copper). Then, a surface of the nickel layer is plated with an aurum (Au) layer having a thickness of 0.03 μm through a displacement reaction. Exposed regions of the electrically-conductive pattern constitute the pads 102.

In some embodiments, in the above mask 002 provided in embodiments of the

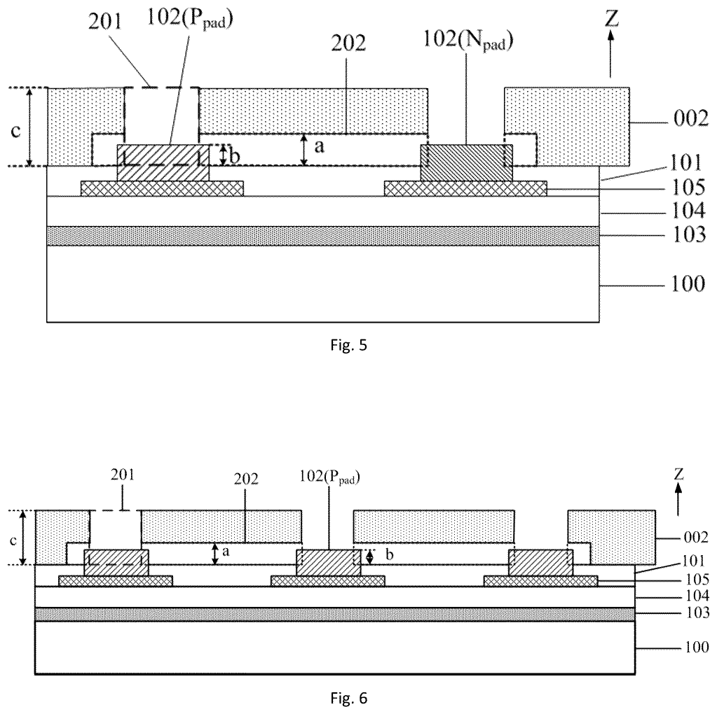

disclosure, as shown in FIG. 5 and FIG. 6, size ‘a’ of the blind hole 202 in the thickness direction Z of the mask 002 is less than or equal to ⅓ of thickness ‘c’ of the mask 002, such that the situation that since the mask 002 is too thin and likely to deform, service life and masking effect of the mask 002 are affected is avoided. Optionally, thickness ‘c’ of the mask 002 is 30 μm. Size ‘a’ of the blind hole 202 in the thickness direction Z of the mask 002 is greater than size ‘b’ of the pad 102 protruding from the insulation layer 101 and is equal to or less than 10 μm. Since a surface of the pad 102 goes beyond a surface of the insulation layer 101 by size ‘b’ in the thickness direction Z, and ‘b’ is greater than or equal to 1 μm and less than or equal to 3 μm, in the thickness direction Z of the mask 002, a space between the blind hole 202 and the pad 102 is equal to (a-b), that is, greater than 0 and less than or equal to (7 μm-9 μm). A space between the blind hole 202 and the insulation layer 101 is equal to ‘a’, that is, greater than or equal to (1 μm to 3 μm) and less than or equal to 10 μm. It can be seen that the space between the blind hole 202 and the pad 102 and the space between the blind hole 202 and the insulation layer 101 are small, such that after the solder metal (such as solder paste) falls onto the pad 102 through the through hole 201, it is difficult for the solder paste to flow and enter the space having a small size due to certain viscosity of the solder paste, and a short circuit between adjacent pads 102 caused by the solder paste is effectively avoided.

In some embodiments, in the above mask 002 provided in embodiments of the disclosure, as shown in FIG. 4-FIG. 6, the orthographic projection of the through hole 201 on the substrate 100 is located within the orthographic projection of the pad 102 on the substrate 100, such that the solder metal (such as solder paste) can fall onto the corresponding pad 102 through the through hole 201, and a short circuit between adjacent pads 102 caused by the solder paste is avoided. Optionally, the size of the through hole 201 is the same as the size of the pin of the electronic element electrically connected to the pad 102. In some embodiments, the size of the through hole 201 may be finely adjusted on the basis of the size of the pin of the electronic element, such that it is ensured that the solder metal transferred to the pad 102 through the through hole 201 may be completely located between the pin of the electronic element and the pad 102 after the reflow soldering process, and an effect of an electrical connection between the pin of the electronic element and the pad 102 is ensured.

In some embodiments, in the above mask 002 provided in embodiments of the

disclosure, as shown in FIG. 2-FIG. 4, the back plate 001 may include a plurality of pixel regions P. Each pixel region P includes three sub-pixels having different colors. Each sub-pixel is a light-emitting diode. One pad group 102′ corresponds to one light-emitting diode. One pad group 102′ includes two pads 102. One through hole group 201′ includes the same number of through holes 201 as the pads 102 of one pad group 102′. At least two adjacent through holes 201 form a through hole group 201′ corresponding to one pad group 102′. One pixel region P corresponds to at least two through hole groups 201′. One blind hole 202 surrounds the through holes 201 of the at least two through hole groups 201′ corresponding to one pixel region P. That is, the blind holes 202 surrounding the through holes 201 of at least two through hole groups 201′ corresponding to one pixel region P are in communication with each other. Therefore, the blind hole 202 has a greater size and is easy to manufacture. Moreover, since the space between the blind hole 202 and the pad 102 and the space between the blind hole 202 and the insulation layer 101 are both small, after the solder metal (such as solder paste) falls onto the pad 102 through the through hole 201, it is difficult for the solder paste to flow and enter the space having a small size due to certain viscosity, and a short circuit between different pads 102 in a region corresponding to the same blind hole 202 caused by the solder paste is effectively avoided. In some other embodiments, one pad group 102′ may include the same number of pads 102 as pins of an electronic element. One through hole group 201′ includes the same number of through holes 201 as pads 102 of one pad group 102′.

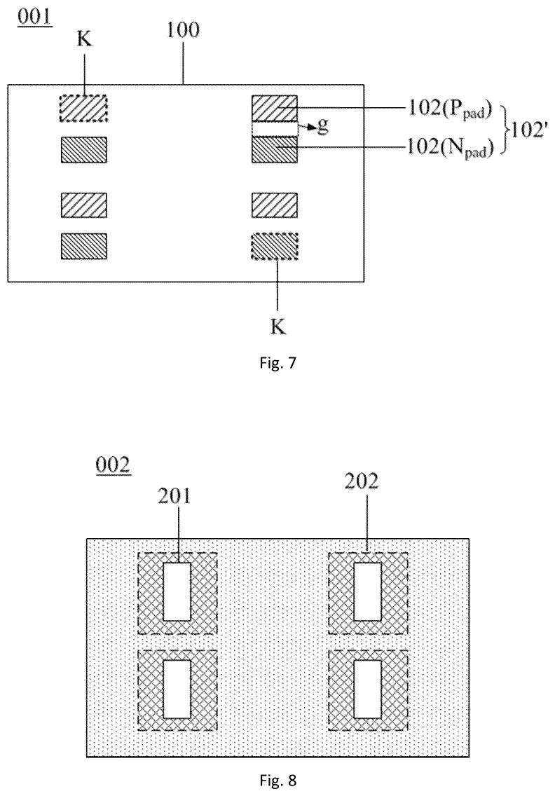

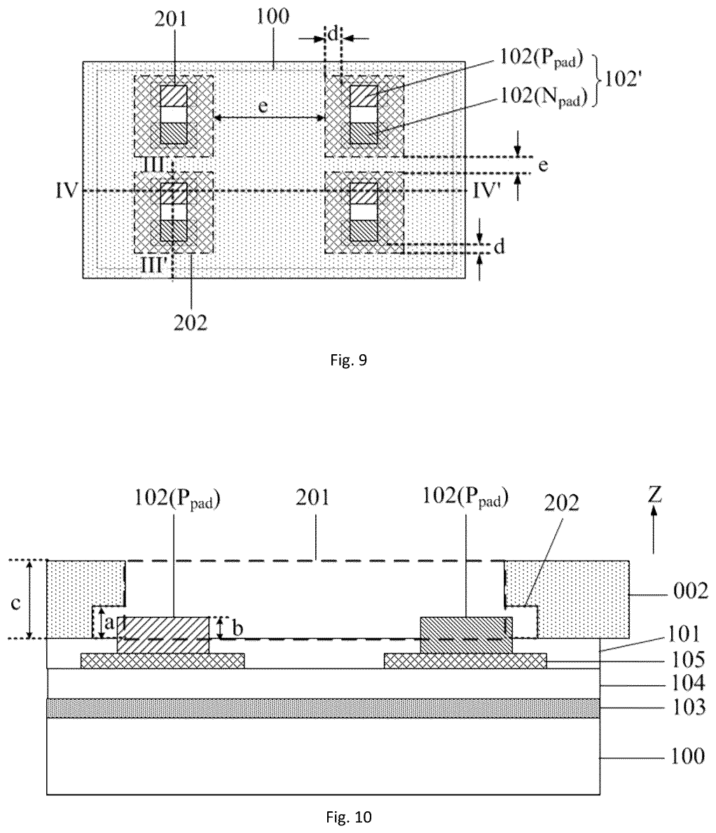

In some embodiments, the mask 002 provided in embodiments of the disclosure may be used to transfer a welding auxiliary material (such as a flux). In this case, as shown in FIG. 7-FIG. 10, the orthographic projection of the through hole 201 on the substrate 100 may be set to be located within the orthographic projection of the pad group 102′ on the substrate 100, and the orthographic projection of the through hole 201 on the substrate 100 overlaps the orthographic projections of at least two pads 102 in the pad group 102′ on the substrate 100, and the orthographic projection of region ‘g’ between adjacent pads 102 on the substrate 100. During specific implementation, the welding auxiliary material (such as a flux) may simultaneously fall onto at least two pads 102 of the pad group 102′ and region ‘g’ between adjacent pads 102 through the same through hole 201. However, since the flux only plays a role in promotion of a soldering process and oxidation prevention, and has no electrical conductivity, a short circuit may not occur between at least two pads 102 of the pad group 102′ by means of the flux. Moreover, compared with the through hole 201 of which the orthographic projection is located within the pad 102 as shown in FIG. 4, the through hole 201 of which the orthographic projection is located within the pad group 102′ as shown in FIG. 9 has a greater aperture and is easier to manufacture.

In some embodiments, in the above mask 002 provided in embodiments of the disclosure, as shown in FIG. 7-FIG. 9, one blind hole 202 may surround one through hole 201 in a case that the orthographic projection of the through hole 201 on the substrate 100 overlaps the orthographic projections of at least two pads 102 in the pad group 102′ on the substrate 100 and the orthographic projection of region ‘g’ between adjacent pads 102 on the substrate 100. In some embodiments, a large blind hole having the same depth as the blind hole 202 may be first formed in a region at which a blind hole 202 is to be formed and a region at which a through hole 201 is to be formed and which surrounds the blind hole. Then, the through hole 201 may be formed in a region of the large blind hole corresponding to the through hole 201. A region of the large blind hole corresponding to the blind hole 202 may be used as the blind hole 202. In this way, even though one blind hole 202 only surrounds one through hole 201, since the through hole 201 of which the orthographic projection is located within the pad group 102′ has a large aperture, the aperture of the large blind hole is correspondingly greater. Thus, manufacture difficulty of the large blind hole is low, and manufacture of the blind hole 202 is facilitated.

In some embodiments, in the above mask 002 provided in embodiments of the disclosure, as shown in FIG. 4 and FIG. 9, the orthographic projection of the blind hole 202 on the substrate 100 extends in a direction away from the through hole 201 relative to the orthographic projection of the pads 102 on the substrate 100. That is, the orthographic projection of the blind hole 202 on the substrate 100 goes beyond the orthographic projection of the pads 102 on the substrate 100. In this way, the mask 002 can better avoid the pads 102 at the blind hole 202, and stress concentration caused by an overlap between the mask 002 and an edge of the pad 102 can be prevented, such that a damage to a circuit of the back plate 001 caused by the stress concentration is effectively avoided.

In some embodiments, a manufacture tolerance of the blind hole 202 is 10 μm, and an alignment tolerance of the mask 002 and the back plate 001 is 20 μm. In order to prevent the mask 002 from overlapping the pad 102, in the above mask 002 provided in embodiments of the disclosure, as shown in FIG. 4 and FIG. 9, distance ‘d’ between the orthographic projection of a boundary of the blind hole 202 away from the through hole 201 on the substrate 100 and the orthographic projection of the pad 102 on the substrate 100 is greater than or equal to 30 μm.

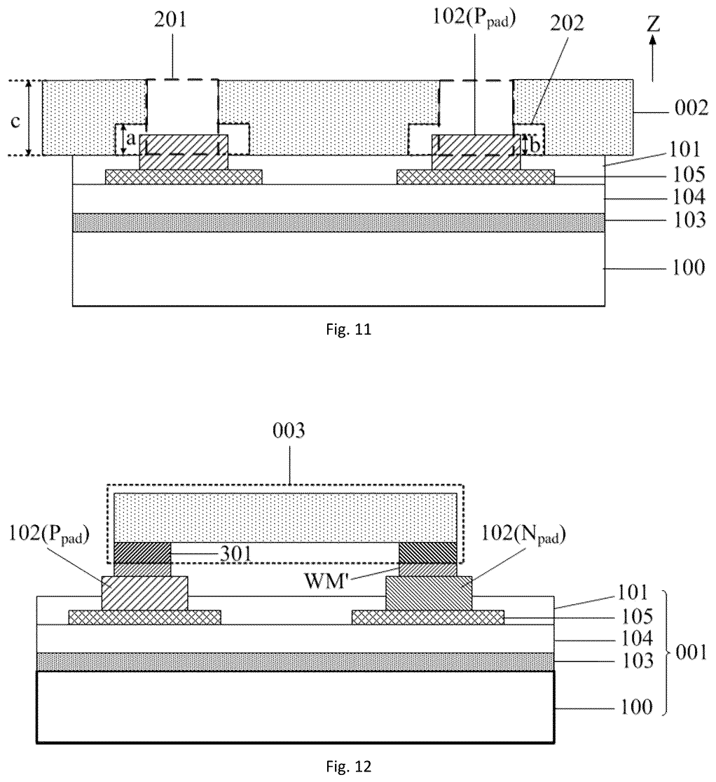

In some embodiments, in the above mask 002 provided in embodiments of the disclosure, as shown in FIG. 11, a portion of the mask 002 between adjacent blind holes 202 makes contact with the insulation layer 101 of the back plate 001. In order to ensure that the mask 002 and the insulation layer 101 have a great contact surface, effectively support the mask 002 by the insulation layer 101, and ensure structural stability of the mask 002, it is required to appropriately set a size of the mask 002 between adjacent blind holes 202. In the disclosure, as shown in FIG. 4 and FIG. 9, distance ‘e’ between two adjacent blind holes 202 is set to be greater than or equal to 100 μm, for example, set to be 200 μm or 300 μm.

On the basis of the same inventive concept, embodiments of the disclosure further provide an electronic apparatus. As shown in FIG. 12, the electronic apparatus includes: an electronic element 003, and the above back plate 001 provided in embodiments of the disclosure. The back plate 001 may be masked by the above mask 002. The electronic element 003 is electrically connected to the pad group including pads 102 of P_{pad} and N_{pad}. In some embodiments, one electronic element 003 is correspondingly electrically connected to one pad group. The electronic element 003 may be a light-emitting diode, a driver chip, etc.

In some embodiments, as shown in FIG. 5, FIG. 6, FIG. 10 and FIG. 11, the back plate 001 provided in embodiments of the disclosure may further include a first electrically-conductive layer 103, a planarization layer 104, a second electrically-conductive layer 105, etc. The first electrically-conductive layer 103 and the second electrically-conductive layer 105 may be made of copper (Cu), etc. The first electrically-conductive layer 103 and the second electrically-conductive layer 105 are used to manufacture a circuit for driving the electronic element 003 to work. Other essential components of the back plate 001 would be understood by those of ordinary skill in the art and will not be repeated herein, and should not be regarded as a limitation on the disclosure.

In some embodiments, the above electronic apparatus provided in embodiments of the disclosure may be a mobile phone, a tablet computer, a television, a monitor, a laptop, a digital photo frame, a navigator, a smart watch, a fitness wristband, a personal digital assistant and other products or components having display functions. The electronic apparatus includes but is not limited to a radio frequency unit, a network module, an audio output and input unit, a sensor, a display unit, a user input unit, an interface unit, a memory, a processor, a power supply, etc. In addition, those skilled in the art can understand that the above structure does not limit the above electronic apparatus provided in embodiments of the disclosure. In other words, the above electronic apparatus provided in embodiments of the disclosure can include more or less components, or combinations of some components, or different component arrangements.

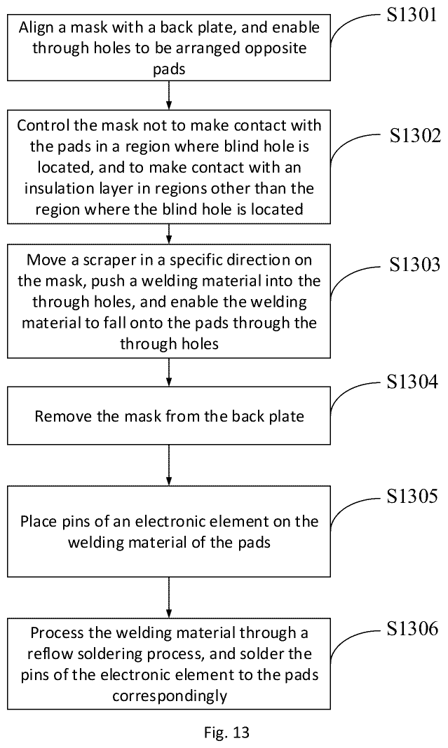

On the basis of the same inventive concept, embodiments of the disclosure further provide a manufacturing method for an electronic apparatus. As shown in FIG. 13, the method includes steps as follows.

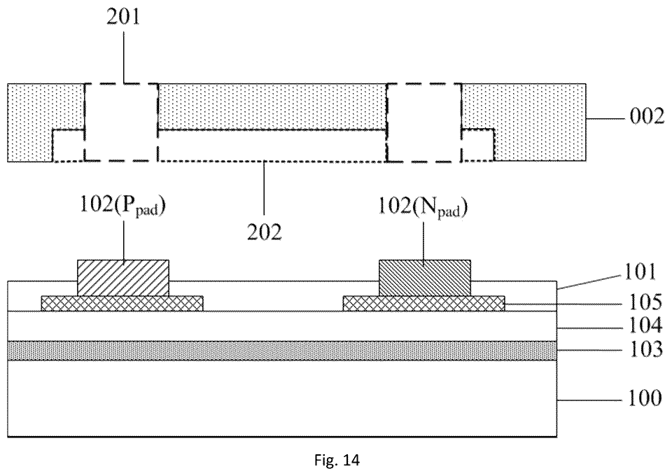

S1301: Align the mask 002 provided in embodiments of the disclosure with a back plate 001, and enable through holes 201 to be arranged opposite pads 102, as shown in FIG. 14.

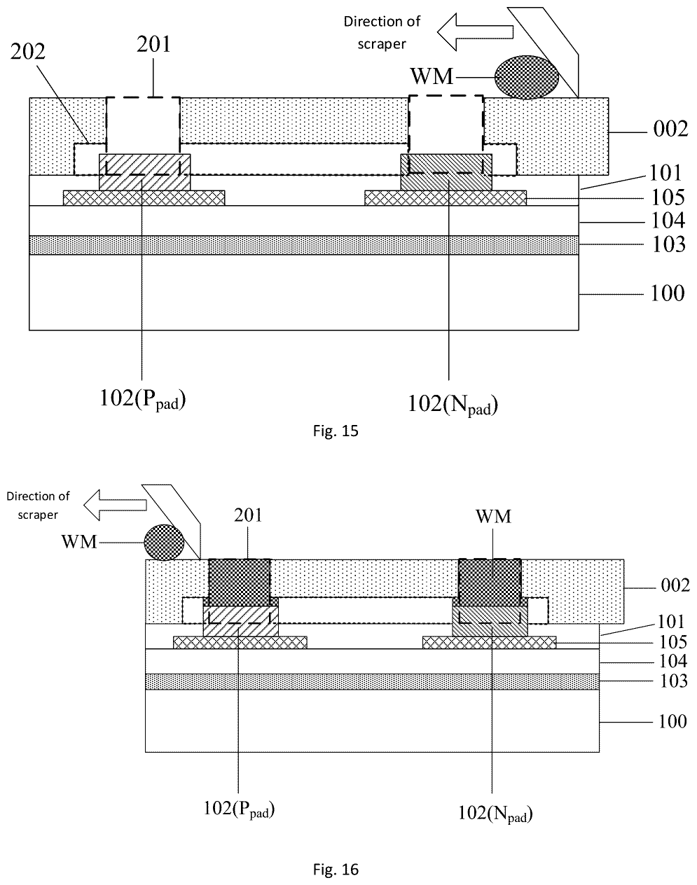

S1302: Control the mask 002 not to make contact with the pads 102 in regions where the blind hole 202 is located, and to make contact with an insulation layer 101 in regions other than the regions where the blind hole 202 is located, as shown in FIG. 15.

S1303: Move a scraper in a specific direction on the mask 002, push a welding material WM into the through holes 201, and enable the welding material WM to fall onto the pads 102 through the through holes 201, as shown in FIG. 16.

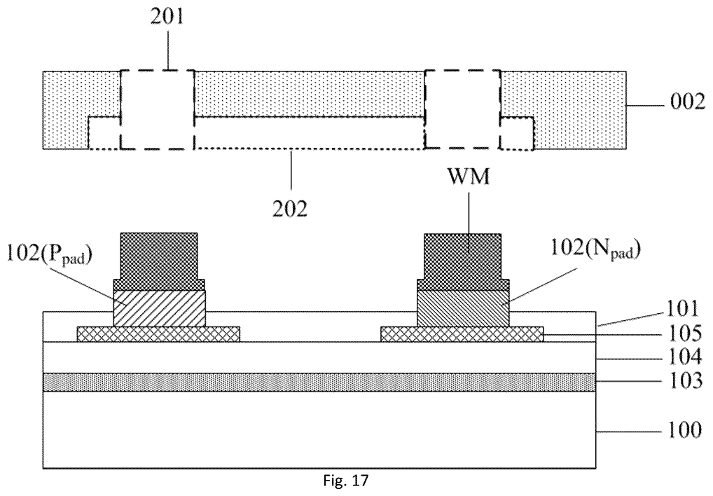

S1304: Remove the mask 002 from the back plate 001, as shown in FIG. 17.

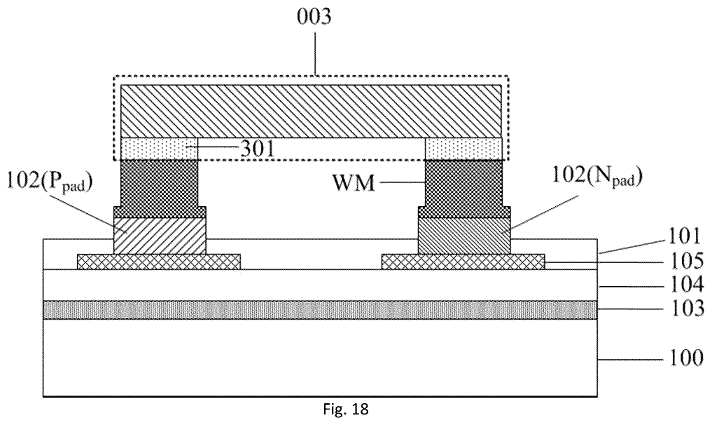

S1305: Place pins 301 of an electronic element 003 on the welding material WM of the pads 102, as shown in FIG. 18.

S1306: Process the welding material WM through a reflow soldering process, and solder the pins 301 of the electronic element 003 to the pads 102 correspondingly, as shown in FIG. 12.

It should be noted that the welding material WM in the disclosure may be one of a solder metal (such as solder paste) or a welding auxiliary material (such as a flux). In a case that the welding material WM is solder paste, each pin 301 of the electronic element 003 may be provided with a flux. After a reflow soldering process, each pin 301 of the electronic element 003 may be electrically connected to the corresponding pad 102 by means of a solidified solder metal. In a case that the welding material WM is a flux, since the flux only promotes the soldering process, has the function of oxidation prevention and does not have electrical conductivity, it is required to arrange a solder metal (such as solder paste) on each pin 301 of the electronic element 003. After the reflow soldering process, each pin 301 of the electronic element 003 can be electrically connected to the corresponding pad 102 by means of the solidified solder metal. During specific implementation, in the reflow soldering process, the solder metal is molten at a high temperature to partially form an intermetallic compound (IMC) with a surface material of the pad 102. Then, the solder metal and/or the intermetallic compound are solidified in a cooling process to form a connection portion WM′, such that each pin 301 of the electronic element 003 is electrically connected to the corresponding pad 102 by means of the connection portion WM′, as shown in FIG. 12. A shape of the orthographic projection of the connection portion WM′ on the substrate 100 is limited by shapes of the orthographic projections of the pin 301 and the pad 102 on the substrate 100. Generally, the shapes of the orthographic projections of the connection portion WM′ and the pin 301 electrically connected thereto on the substrate 100 are substantially the same as the shape of the orthographic projection of the pad 102 on the substrate 100, for example, approximately circular or square.

Although the disclosure describes preferred embodiments, it should be understood that those skilled in the art can make various modifications and variations to the embodiments of the disclosure without departing from the spirit and scope of the embodiments of the disclosure. In this way, if these modifications and variations of embodiments of the disclosure fall within the scope of the claims of the disclosure and their equivalent technologies, the disclosure is further intended to include these modifications and variations.

1. A mask, configured to mask a back plate, wherein the back plate comprises a substrate, and an insulation layer and a pad group that are located on the substrate, the pad group comprises at least two pads, the insulation layer comprises openings, and the pads protrude towards a side away from the substrate relative to the insulation layer at the openings; and
the mask comprises:
through holes, wherein orthographic projections of the through holes on the substrate overlap orthographic projections of the pads on the substrate; and
a blind hole, wherein the blind hole surround the through holes, a size of the blind hole in a thickness direction of the mask is greater than or equal to a size of the pad protruding from the insulation layer, and an orthographic projection of the blind hole on the substrate and the orthographic projections of the through holes on the substrate after spliced cover the orthographic projections of the pads on the substrate.

2. The mask according to claim 1, wherein the size of the blind hole in the thickness direction of the mask is less than or equal to ⅓ of a thickness of the mask.

3. The mask according to claim 2, wherein the orthographic projections of the through holes on the substrate are located within the orthographic projection of the pads on the substrate.

4. The mask according to claim 3, wherein the back plate comprises a plurality of pixel regions, at least every two adjacent through holes form a through hole group corresponding to one pad group, one pixel region corresponds to at least two through hole groups, and one blind hole surrounds through holes in the at least two through hole groups corresponding to one pixel region.

5. The mask according to claim 2, wherein the orthographic projections of the through holes on the substrate are located within an orthographic projection of the pad group on the substrate, and the orthographic projections of the through holes on the substrate overlap orthographic projections of the at least two pads of the pad group on the substrate and an orthographic projection of a space between the pads on the substrate.

6. The mask according to claim 5, wherein one blind hole surrounds one through hole.

7. The mask according to claim 1, wherein the orthographic projection of the blind hole on the substrate extends in a direction away from the through hole relative to the orthographic projection of the pad on the substrate.

8. The mask according to claim 7, wherein a distance between an orthographic projection of a boundary of the blind hole away from the through hole on the substrate and the orthographic projection of the pad on the substrate is greater than or equal to 30 μm.

9. The mask according to claim 8, wherein a distance between two adjacent blind holes is greater than or equal to 100 μm.

10. An electronic apparatus, comprising an electronic element and a back plate, wherein the electronic element is electrically connected to a pad group, and the back plate is masked by the mask according to claim 1.

11. A manufacturing method for an electronic apparatus according to claim 10, comprising:
aligning the mask with the back plate, and enabling the through holes to be arranged opposite pads;
controlling the mask not to make contact with the pads in a region where the blind hole is located, and to make contact with an insulation layer in regions other than the region where the blind hole is located;
moving a scraper in a direction on the mask, pushing a welding material into the through holes, and enabling the welding material to fall onto the pads through the through holes;
removing the mask from the back plate;
placing pins of an electronic element on the welding material of the pads; and
processing the welding material through a reflow soldering process, and soldering the pins of the electronic element to the pads correspondingly.
